(19) United States
(12) Patent Application Publication
(10) Pub. No.: US 2005/0274872 A1
(43) Pub. Date: Dec. 15, 2005

(54) Contact image sensor module

(76) Inventors: Ming-Der Chou, Taipei City (TW); Jung-Chiao Chang, Taipei City (TW)

Correspondence Address: BIRCH STEWART KOLASCH & BIRCH, PO BOX 747, FALLS CHURCH, VA, 22040-0747, US

(21) Appl. No.: 10/865,925

(22) Filed: Jun. 14, 2004

(51) Int. Cl. H01L 27/00

(52) U.S. Cl. 250/208.1

(57) ABSTRACT

A contact image sensor module has a light source, at least one reflective element and a photoelectric conversion element. The photoelectric conversion element is arranged between the light source and the reflective element, such that the light from the light source is directed toward the manuscript. The reflective element receives the light reflected from the manuscript, and then the light is reflected back to the manuscript. The photoelectric conversion element receives light directed from the light source and the reflective element toward the manuscript, and then the light is converted into an electric signal, thus eliminating the dark band problem of the manuscript.

### BACKGROUND OF THE INVENTION

1. Field of the Invention

The present invention relates to a contact image sensor module, and particularly to a contact image sensor module for eliminating some problems, such as, the dark band produced on a manuscript, etc.

2. Description of the Prior Art

Previously, an image scanner used a CCD (charge coupled device) as its image sensor. However, since Canon successfully developed a full-color CIS (contact image sensor) in 1997, an additional choice is available for the sensor element of an image scanner. Currently, the CIS scanner is more commonly used in low-level scanner products and facsimile devices, and thus the photosensitive elements of high-level scanners mainly use CCDs. On the other hand, the assembling cost of a CIS scanner is cheaper than that of a CCD scanner, and the manufacturing process is simpler. The CIS scanner is further cheap, light and thin, thus enabling the product to be competitive in the market.

With reference to FIGS. 1 and 2, when a manuscript is scanned with a CIS scanner, the manuscript 10a is placed on the glass panel 30a of the scanning frame 20a. The contact image sensor (CIS) 40a inside the scanning frame 20a emits light and receives the reflecting light from the manuscript 10a, and then transforms the reflected light into electrical signals. As the contact image sensor (CIS) module 40a is mechanically moved, the whole manuscript 10a is scanned. In this case, the contact image sensor (CIS) module 40a includes a light source 50a and a adjacent photoelectric converter element 60a, and the light source 50a comprises a light-emitting diode (LED) 51a and a light-guiding element 52a. The scanning procedure of the manuscript 10a with the contact image sensor (CIS) module 40a is as follows: the LED 51a emits light, and the light is guided by the light-guiding diode 52a to enter obliquely the surface of the manuscript 10a placed on the glass panel 30a. Meanwhile the photoelectric converter element 60a receives and transforms the light reflected from the manuscript 10a into the electrical signals. The contact image sensor (CIS) module 40a is mechanically moved by its mechanical actuating unit (not shown) to scan the whole surface of the manuscript 10a.

With reference to FIG. 1, the manuscript 10a receives the oblique incident light from the light source 50a, so an included angle θ between the terminal edge of the manuscript 10a and the light source 50a is formed, resulting in the dark band within the included angle θ. Therefore, the reflecting light from the dark band cannot be received when the contact image sensor (CIS) module 40a is scanning the manuscript 10a. Thus, when the signals produced by the photoelectric conversion element 60a are converted into an image, the portion in the image corresponding to the terminal edge of the manuscript 10a is formed as an dark band, which is inaesthetic. As a result, it is required to further amend the image to improve the image for further use, thus resulting in inconvenience when using the above mentioned operations.

With reference to FIGS. 3 and 4, to solve the dark band problem, a further light source 50a is arranged on the opposite side of the photoelectric conversion element 60a, such that the light from both of the light sources 50a are arranged to fall on the manuscript 10a at an included angle, thus eliminating the dark band produced by using light source 10a on a single side. However, due to the arrangement of an additional light source 50a, it results in additional manufacturing and material costs, thereby resulting in the degradation of the competitive power of the products.

Accordingly, this invention is provided to improve the above disadvantages with a reasonable design.

### SUMMARY OF THE INVENTION

The primary object of the present invention is to apply at least one reflective element for enabling reflecting light from the manuscript back to the manuscript again, thereby to eliminate the dark band produced on the manuscript and reduce the material and manufacturing costs.

According to the above mentioned objects of this invention, this invention provides a contact image sensor module, which includes a light source, at least one reflective element and a photoelectrical conversion element arranged between the light source and the reflective element. The reflective element is provided for receiving reflecting light from a manuscript onto which the light source emits illuminating light, and the reflecting light is reflected back to the manuscript. The photoelectrical conversion element is provided for receiving light directed from the light source and the reflective element toward the manuscript, and the light is converted into an electric signal.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a side view schematically showing the structure of a conventional CIS module;

FIG. 2 is a top view of FIG. 1;

FIG. 3 is a side view schematically showing the structure of another conventional CIS module;

FIG. 4 is a top view of FIG. 3;

FIG. 5 is a side view of a scanner according to the present invention; and

FIG. 6 is a top view of the contact image sensor module according to the present invention.

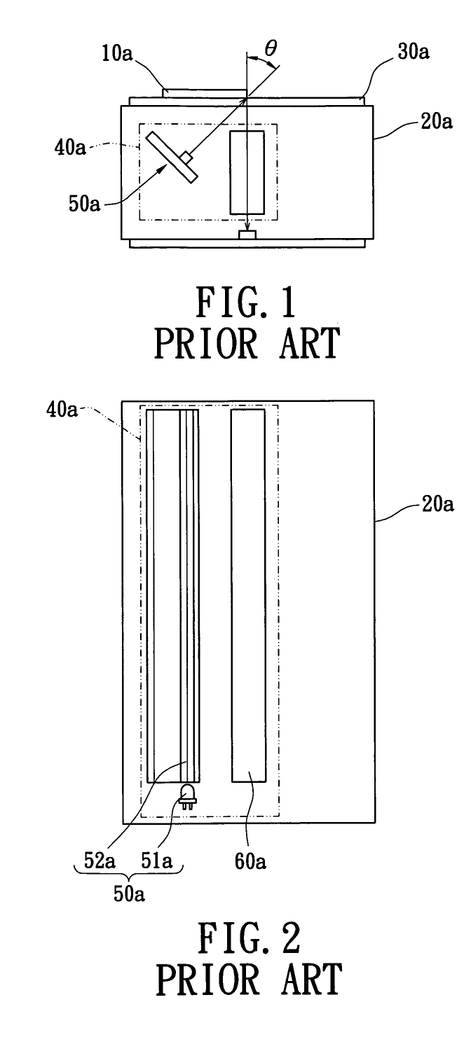

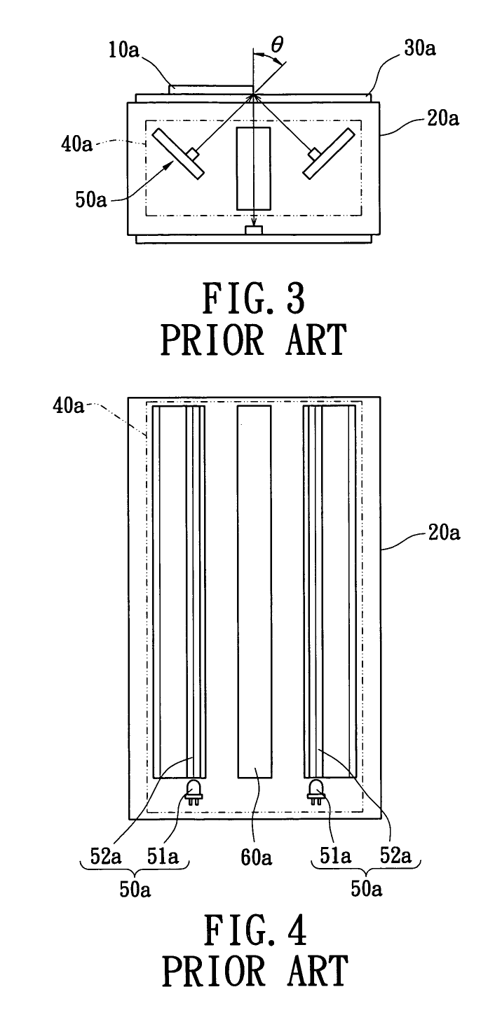

### DESCRIPTION OF THE PREFERRED EMBODIMENT

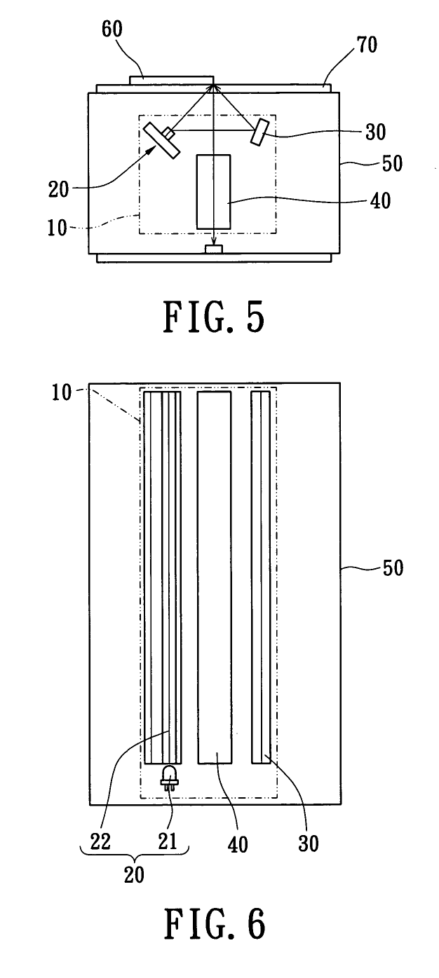

With reference to FIGS. 5 and 6, the present invention provides a contact image sensor (CIS) module 10 adapted to a scanner. The contact image sensor module includes a light source 20, at least one reflective element 30 and a photoelectric conversion element 40. The contact image sensor module 10 can be movably arranged within the scanning frame 50 of the scanner, and a manuscript 60 is placed on the glass panel 70 of the scanning frame 50. The light source 20 emits illuminating light obliquely onto the surface of the manuscript 60. The reflective element 30 receives reflecting light from the manuscript 60 onto which the light source 20 emits the illuminating light, and the reflecting light is reflected back to the manuscript 60. The photoelectric conversion element 40 thus is arranged between the light source 20 and the reflective element 30 for receiving light directed from the light source 20 and the reflective element 30 toward the manuscript 60, and the light is converted into an electric signal. Accordingly, the dark band of the manuscript 60 can be eliminated by means of the reflecting light from the manuscript back to the manuscript again.

With reference to FIG. 6, the light source 20 includes a light-emitting element 21 and a light-guiding element 22 adjacent to the light-emitting element 21 for receiving the illuminating light of the light-emitting element 21, and the illuminating light is guided out from an upper side of the light-guiding element 22 and emitted onto the manuscript 60. Perfectly, the light-emitting element 21 can be a light emitting diode (LED). Perfectly, the light-guiding element 22 can be a transparent plastic strip with a rectangular shape in a cross-section. Additionally, the reflective element 30 can be a reflecting mirror or a reflecting aluminum plate with a rectangular shape in a cross-section.

In this way, the light of the light-emitting element 21 is emitted onto the surface of the manuscript 60 through the light-guiding element 22, and then received by the reflective element 30. Afterwards, the received light is reflected back to the manuscript 60, thus eliminating the dark band produced due to the fact that the light from the light-emitting element 21 cannot reach the terminal lateral surface of the manuscript 60, such that the range of the included angle θ between the light source 20 and the terminal edge of the manuscript 60 is covered by the illumination of the reflective element 30. Therefore, when the reflected light from the manuscript 60 is received by the photoelectric conversion element 40 and converted into electrical signals, and after the electrical signals are reproduced by the processing unit (not shown) to an image, there is no dark band at the terminal edge of the image. Consequently, the problem of the dark band during scanning operation of the exist scanner can be solved by using this simple structural design.

To sum up, the contact image sensor module according to this invention is arranged with a reflective element for reflecting the reflecting light from the manuscript back to the manuscript, thus eliminating the dark band of the manuscript as well as reducing the material and manufacturing costs.

Although possible embodiments of the invention have been described above, it is to be understood that the scope of the invention is not limited to these embodiments; in the same way, all equivalent structures and modifications as implemented in this specification and as illustrated in these drawings are covered within the scope of this invention, in order to protect the right of the inventor.

1. A contact image sensor module comprising:
a light source;
at least one reflective element for receiving reflecting light from a manuscript onto which the light source emits illuminating light, and the reflecting light reflected back to the manuscript; and
a photoelectrical conversion element arranged between the light source and the reflective element, and the photoelectrical conversion element for receiving light directed from the light source and the reflective element toward the manuscript, and the light converted into an electric signal.

2. The contact image sensor module according to claim 1, wherein the light source includes a light-emitting element and a light-guiding element adjacent to the light-emitting element for receiving the illuminating light of the light-emitting element, and the illuminating light is guided out from an upper side of the light-guiding element and emitted onto the manuscript.

3. The contact image sensor module according to claim 2, wherein the light-guiding element has a rectangular shape in a cross-section as a strip-shaped.

4. The contact image sensor module according to claim 2, wherein the light-emitting element is a light-emitting diode (LED).

5. The contact image sensor module according to claim 2, wherein the light-emitting element is a white light-emitting diode (W-LED).

6. The contact image sensor module according to claim 1, wherein the reflective element is a reflecting mirror.

7. The contact image sensor module according to claim 1, wherein the reflective element is a reflecting aluminum plate.
